(19) United States
(12) Patent Application Publication
(10) Pub. No.: US 2025/0120072 A1
(43) Pub. Date: Apr. 10, 2025

(54) MEMORY DEVICE AND SEMICONDUCTOR PACKAGE INCLUDING THE SAME

(71) Applicant: SAMSUNG ELECTRONICS CO., LTD., Suwon-si (KR)

(72) Inventors: Seryeun YANG, Suwon-si (KR); Jinwoo HAN, Suwon-si (KR); Jeonil LEE, Suwon-si (KR)

(21) Appl. No.: 18/829,537

(22) Filed: Sep. 10, 2024

(30) Foreign Application Priority Data
Oct. 6, 2023 (KR) 10-2023-0133682

(51) Int. Cl. H10B 12/00; H01L 25/065; H10B 80/00

(52) U.S. Cl. CPC H10B 12/50; H01L 25/0657; H10B 12/36; H10B 80/00; H01L 2225/06541

(57) ABSTRACT

A memory device includes a peripheral circuit layer including a peripheral circuit region. A cell layer is arranged at a different vertical level from the peripheral circuit layer and includes a cell region. A core layer is arranged between the peripheral circuit layer and the cell layer and is electrically connected to the peripheral circuit region and the cell region. The cell region includes a plurality of cell banks each including a memory component. The core circuit region includes a plurality of core banks arranged at positions at least partially vertically overlapping the plurality of cell banks, respectively. Each of the plurality of core banks includes a core circuit.

### CROSS-REFERENCE TO RELATED APPLICATION

This application claims priority under 35 U.S.C. § 119 to Korean Patent Application No. 10-2023-0133682, filed on Oct. 6, 2023 in the Korean Intellectual Property Office, the disclosure of which is incorporated by reference in its entirety herein.

### 1. TECHNICAL FIELD

The present inventive concept relates to a memory device and a semiconductor package including the same, and more particularly, to a multi-layered memory device and a semiconductor package including the same.

### 2. DISCUSSION OF RELATED ART

The integration level of integrated memory devices has increased along with the advancement of the electronic device industry. In addition, a semiconductor package capable of broadband data input/output has been developed to enable high-speed or smart operation of computing devices. Research is being conducted to develop a memory device that may reduce the size of a memory chip and also have increased performance, and a semiconductor package including the same.

### SUMMARY

Embodiments of the present inventive concept provide a memory device having increased integration and increased performance, and a semiconductor package including the same.

According to an embodiment of the present inventive concept, a memory device includes a peripheral circuit layer including a peripheral circuit region. A cell layer is arranged at a different vertical level from the peripheral circuit layer. The cell layer includes a cell region. A core layer is arranged between the peripheral circuit layer and the cell layer in a vertical direction. The core layer includes a core circuit region electrically connected to the peripheral circuit region and the cell region. The cell region includes a plurality of cell banks. Each of the plurality of cell banks includes a memory component. The core circuit region includes a plurality of core banks arranged at positions at least partially vertically overlapping the plurality of cell banks, respectively. Each of the plurality of core banks includes a core circuit.

According to an embodiment of the present inventive concept, a memory device includes a peripheral circuit layer including a peripheral circuit region and a neural processing unit (NPU) region. A core layer is arranged on the peripheral circuit layer. The core layer includes a core circuit region electrically connected to the peripheral circuit region and the NPU region. A first cell layer is arranged at a vertical level higher than the core layer. The first cell layer includes a first cell region electrically connected to the core circuit region. The first cell region includes a plurality of first cell banks. Each of the plurality of first cell banks includes a memory component. The NPU region includes a plurality of NPU blocks performing an operation function on the plurality of first cell banks.

According to an embodiment of the present inventive concept, a semiconductor package includes a plurality of memory dies vertically stacked. Through-substrate vias (TSVs) electrically connect the plurality of memory dies with each other. Each of the plurality of memory dies comprises a peripheral circuit layer including a peripheral circuit region. A core layer is arranged at a higher vertical level than the peripheral circuit layer. The core layer includes a core circuit region electrically connected to the peripheral circuit region. A cell layer is arranged at a vertical level higher than the core layer. The cell layer includes a cell region electrically connected to the core circuit region. The cell region includes a plurality of cell banks. Each of the plurality of cell banks includes a memory component. The core circuit region includes a plurality of core banks arranged at positions at least partially vertically overlapping the plurality of cell banks, respectively. Each of the plurality of core banks includes a core circuit.

### BRIEF DESCRIPTION OF THE DRAWINGS

Embodiments of the present inventive concept will be more clearly understood from the following detailed description taken in conjunction with the accompanying drawings in which:

FIG. 1 is a perspective view illustrating a memory device according to an embodiment of the present inventive concept;

FIG. 2 is a plan view showing a core layer of FIG. 1 according to an embodiment of the present inventive concept;

FIG. 3 is a plan view showing a cell layer of FIG. 1 according to an embodiment of the present inventive concept;

FIG. 4 is a perspective view illustrating a memory device according to an embodiment of the present inventive concept;

FIG. 5 is a plan view illustrating a peripheral circuit layer of FIG. 4 according to an embodiment of the present inventive concept;

FIG. 6 is a plan view showing a core layer of FIG. 4 according to an embodiment of the present inventive concept;

FIG. 7 is a plan view showing a cell layer of FIG. 4 according to an embodiment of the present inventive concept;

FIG. 8 is a perspective view illustrating a memory device according to an embodiment of the present inventive concept;

FIG. 9 is a plan view illustrating a peripheral circuit layer of FIG. 8 according to an embodiment of the present inventive concept;

FIGS. 10 to 12 are perspective views illustrating a memory device according to embodiments of the present inventive concept;

FIG. 13 is a plan view illustrating a peripheral circuit layer of a memory device according to an embodiment of the present inventive concept;

FIG. 14 is a plan view illustrating a core layer of a memory device according to an embodiment of the present inventive concept;

FIG. 15 is a plan view illustrating a cell layer of a memory device according to an embodiment of the present inventive concept;

FIG. 16 is a schematic diagram illustrating data flow of a memory device according to an embodiment of the present inventive concept;

FIG. 17 is a cross-sectional view illustrating a semiconductor package according to an embodiment of the present inventive concept; and

FIG. 18 is a cross-sectional view illustrating a semiconductor package according to an embodiment of the present inventive concept.

### DETAILED DESCRIPTION OF EMBODIMENTS

Hereinafter, embodiments of the present inventive concept will be described in detail with reference to the accompanying drawings.

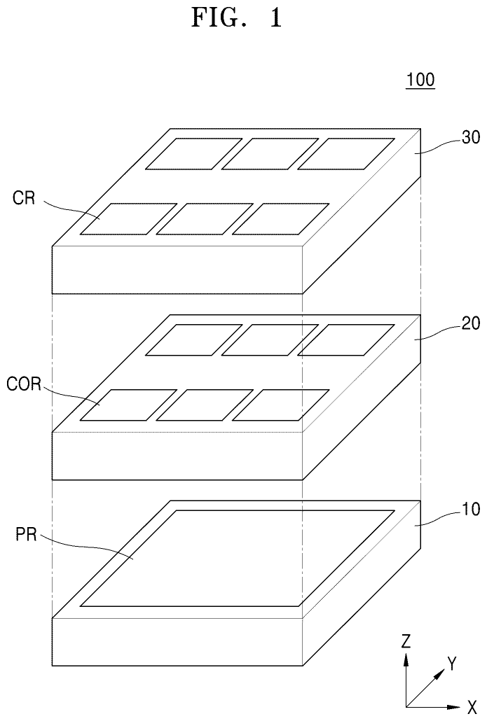

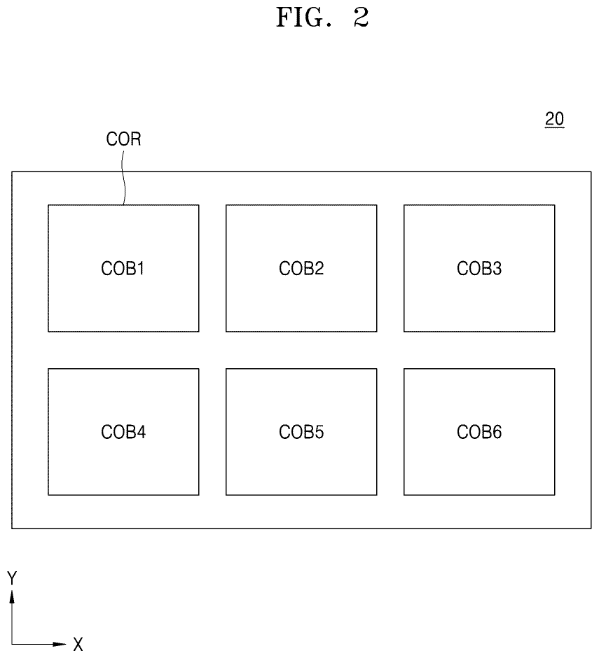

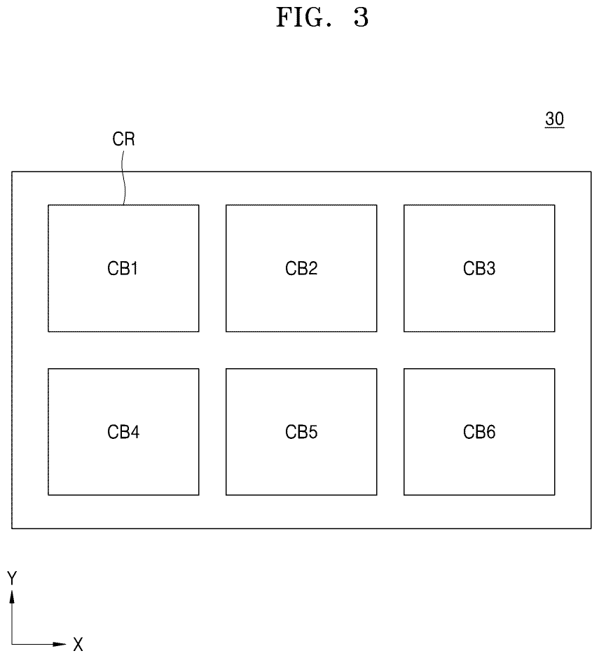

FIG. 1 is a perspective view illustrating a memory device 100 according to an embodiment. FIG. 2 is a plan view showing the core layer 20 of FIG. 1. FIG. 3 is a plan view showing the cell layer 30 of FIG. 1.

Referring to FIGS. 1 to 3, the memory device 100 may include a peripheral circuit layer 10, a core layer 20, and a cell layer 30 arranged in a vertical direction Z. In an embodiment, the cell layer 30 may be arranged at a vertical level different from the peripheral circuit layer 10. The core layer 20 may be arranged between the peripheral circuit layer 10 and the cell layer 30 (e.g., in the vertical direction Z). For example, the core layer 20 may be arranged at a vertical level higher than the peripheral circuit layer 10, and the cell layer 30 may be arranged at a vertical level higher than the core layer 20. However, embodiments of the present inventive concept are not necessarily limited thereto. For example, in an embodiment, the core layer 20 may be arranged at a vertical level higher than the cell layer 10, and the peripheral circuit layer 30 may be arranged at a vertical level higher than the core layer 20. In an embodiment, the peripheral circuit layer 10, the core layer 20, and the cell layer 30 may be arranged to overlap each other in the vertical direction Z.

In an embodiment, the memory device 100 may have a cell-over-peripheral (COP) structure in which the cell layer 30 is arranged at a vertical level higher than the peripheral circuit layer 10. In addition, the memory device 100 may have a three-stack structure in that the core layer 20 is stacked at a higher vertical level than the peripheral circuit layer 10, and the cell layer 30 is stacked at a higher vertical level than the core layer 20. For convenience of understanding, the peripheral circuit layer 10, the core layer 20, and the cell layer 30 are separated in the vertical direction Z, but it will be understood that the core layer 20 is attached to (e.g., directly contacting) the top surface of the peripheral circuit layer 10, and the cell layer 30 is attached to (e.g., directly contacting) the top surface of the core layer 20 to form a three-stack structure.

In an embodiment, the peripheral circuit layer 10, the core layer 20, and the cell layer 30 are formed on separate wafers, and the peripheral circuit layer 10, the core layer 20, and the cell layer 30 are attached to each other in a wafer bonding method to form a memory device 100 having a three-stack structure. However, embodiments of the present inventive concept are not necessarily limited thereto. For example, in an embodiment, the memory device 100 having a three-stack structure may be formed by forming the peripheral circuit layer 10 on a base wafer and sequentially forming the core layer 20 and the cell layer 30 on the base wafer. In an embodiment, the peripheral circuit layer 10 and the core layer 20 may be formed on separate wafers, the peripheral circuit layer 10 and the core layer 20 may be attached to each other in a wafer bonding manner, and then the cell layer 30 may be formed on the core layer 20 to form the memory device 100 having a three-stack structure.

In an embodiment, the peripheral circuit layer 10 may include a peripheral circuit board and peripheral circuits arranged on the peripheral circuit board. The peripheral circuit layer 10 may include a peripheral circuit region PR, and peripheral circuits may be arranged in the peripheral circuit region PR. For example, in an embodiment the peripheral circuit layer 10 may include peripheral circuits, such as timing registers, address registers, data input registers, data output registers and data input/output terminals.

In an embodiment, the core layer 20 may include a core region COR. In an embodiment, the core region COR may include core circuits such as a sub-word line driver, a sense amplifier, a row decoder, a column decoder, and a read/write circuit R/W circuit. The core region COR may also be referred to as a core circuit region. For example, as shown in FIG. 2, in an embodiment the core region COR may include first to third core banks COB1, COB2, and COB3 arranged side by side in the first horizontal direction X, and fourth to sixth core banks COB4, COB5, and COB6 arranged side by side in the first horizontal direction X and spaced apart from the first to third core banks COB1, COB2, and COB3 in a second horizontal direction Y, respectively. The second horizontal direction Y crosses the first horizontal direction X. For example, in an embodiment the second horizontal direction Y may be perpendicular to the first horizontal direction X. However, embodiments of the present inventive concept are not necessarily limited thereto and the core region COR may include a plurality of core banks have various different numbers of core banks. Each of the plurality of core banks may include a core circuit.

In an embodiment, the cell layer 30 may include a cell region CR. The cell region CR may be a region in which memory components are arranged. In an embodiment, the cell region CR may be arranged to at least partially vertically overlap the core region COR. For example, in an embodiment the cell region CR may include first to third cell banks CB1, CB2, and CB3 arranged side by side in the first horizontal direction X, and fourth to sixth cell banks CB4, CB5, and CB6 arranged side by side in the first horizontal direction X and spaced apart from the first to third cell banks CB1, CB2, and CB3 in the second horizontal direction Y, respectively. However, embodiments of the present inventive concept are not necessarily limited thereto and the cell region CR may include a plurality of cell banks have various different numbers of cell banks. Each of the plurality of cell banks may include a memory component.

For example, the first cell bank CB1 may be arranged to vertically overlap the corresponding first core bank COB1, and the first cell bank CB1 may be electrically connected to the corresponding first core bank COB1. In addition, in an embodiment the first cell bank CB1 may be electrically connected to the peripheral circuit region PR in the peripheral circuit layer 10 through the first core bank COB1.

In an embodiment, a memory component included in the cell region CR may include a DRAM device. In some embodiments, the memory component included in the cell region CR may include at least one of a buried channel array transistor, a vertical channel transistor, a vertical stacked DRAM device, and a ferroelectric field-effect transistor (FET). In some embodiments, the memory component included in the cell region CR may be a one transistor-one capacitor (1T-1C) type memory device including one transistor and one capacitor. In some embodiments, the memory component included in the cell region CR may be a capacitor-less type memory device including only one transistor. In some embodiments, the memory component included in the cell region CR may be any one of nonvolatile memory devices, such as a flash memory, a phase-change RAM (PRAM), a magnetic RAM (MRAM), a resistive RAM (RRAM), a ferroelectric RAM (FRAM), and the like.

In some embodiments, the peripheral circuits included in the peripheral circuit layer 10 may include at least one of a planar FET device, a finFET device, and a multi-bridge channel FET device. In an embodiment, the core circuits included in the core layer 20 may include at least one of a planar FET device, a FET device having (e.g., employing) a metal gate and a high dielectric constant dielectric film, a finFET device, and a multi-bridge channel FET device.

In an embodiment, the peripheral circuits included in the peripheral circuit layer 10 may include the same type of device as the core circuits included in the core layer 20. However, embodiments of the present inventive concept are not necessarily limited thereto. For example, in some embodiments the peripheral circuits included in the peripheral circuit layer 10 may include a different type of device from the core circuits included in the core layer 20. For example, the peripheral circuits included in the peripheral circuit layer 10 may include multi-bridge channel FET devices, and the core circuits included in the core layer 20 may include planar FET devices.

In some embodiments, the peripheral circuit layer 10 may further include a through substrate via (TSV), and the peripheral circuits included in the peripheral circuit layer 10 may be electrically connected to the core circuits included in the core layer 20 through the TSV. In addition, the core layer 20 may further include the TSV, and the core circuits included in the core layer 20 may be electrically connected to the memory components included in the cell layer 30 through the TSV.

According to an embodiment, peripheral circuits may be arranged in the peripheral circuit layer 10, core circuits may be arranged in the core layer 20, and memory components may be arranged in the cell layer 30. Therefore, compared to a comparative embodiment in which a cell region, a core region, and a peripheral circuit region are formed on one substrate, the chip size may be reduced, and the degree of freedom of space utilization of each of the peripheral circuit layer 10, the core layer 20, and the cell layer 30 may be increased. In particular, the electrical performance of peripheral circuits and core circuits respectively formed in the peripheral circuit layer 10 and the core layer 20 may be increased, while the degree of integration and electrical performance of memory components formed in the cell layer 30 may be increased.

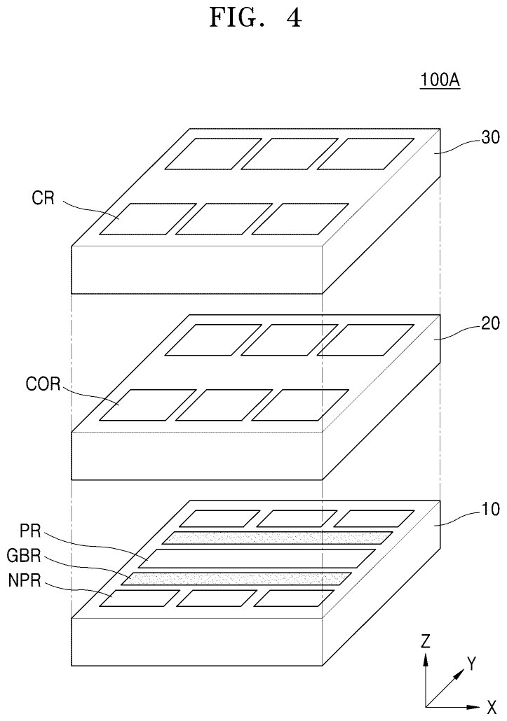

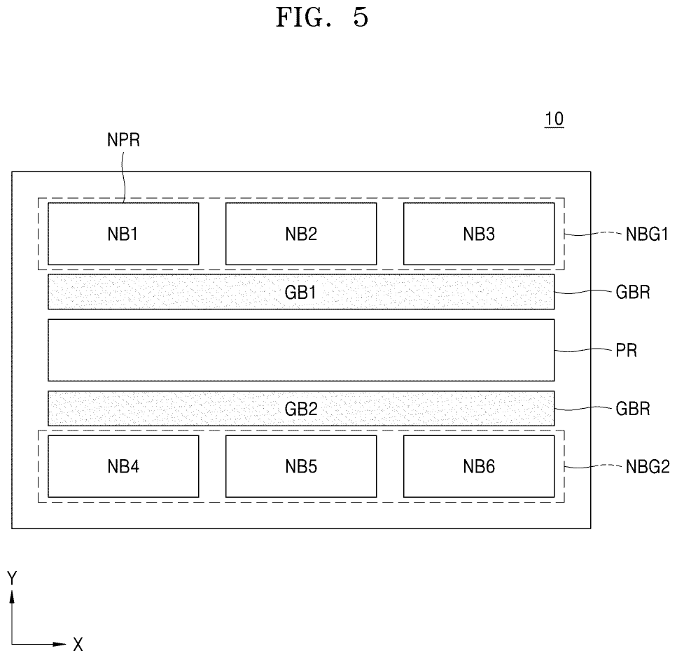

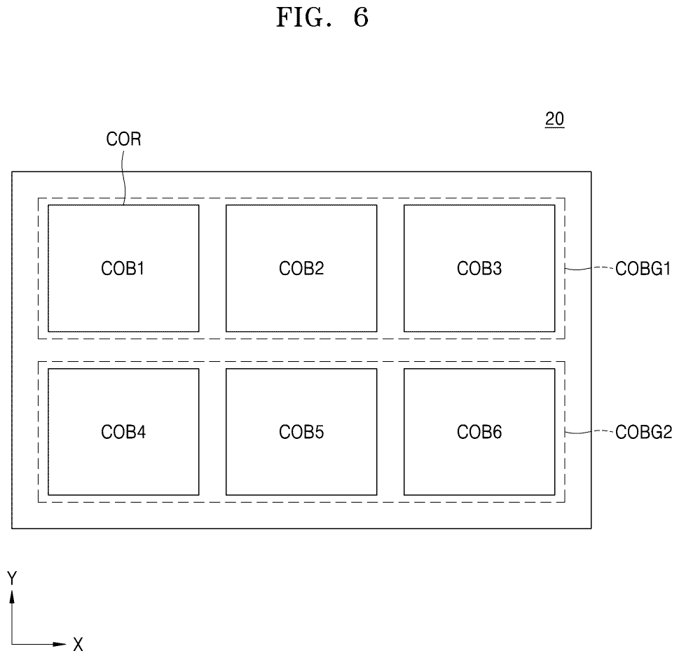

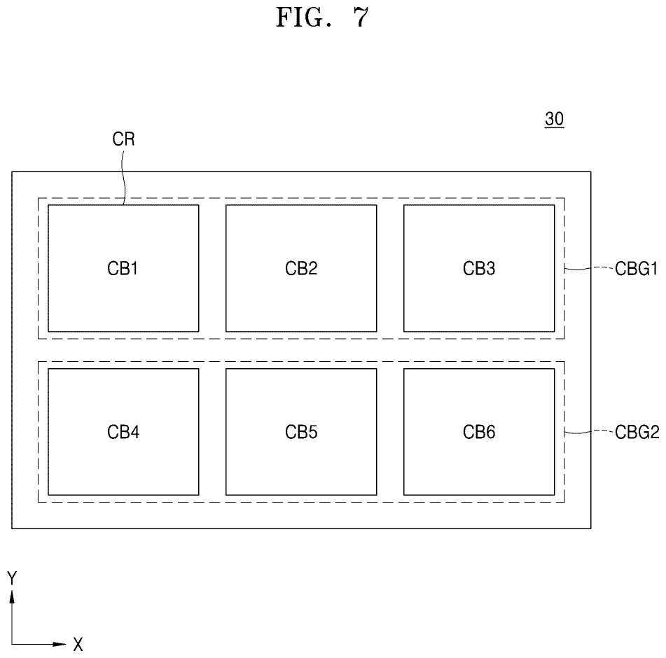

FIG. 4 is a perspective view illustrating a memory device 100A according to embodiments. FIG. 5 is a plan view illustrating the peripheral circuit layer 10 of FIG. 4. FIG. 6 is a plan view showing the core layer 20 of FIG. 4. FIG. 7 is a plan view showing the cell layer 30 of FIG. 4.

Referring to FIGS. 4 to 7, the memory device 100A may include a peripheral circuit layer 10, a core layer 20, and a cell layer 30 consecutively arranged in a vertical direction Z.

In an embodiment, the peripheral circuit layer 10 may include a peripheral circuit board and peripheral circuits arranged on the peripheral circuit board. In an embodiment, the peripheral circuit layer 10 may include a peripheral circuit region PR, a neural processor unit (NPU) region NPR, and a global bus region GBR.

In an embodiment, the NPU region NPR may include circuits that perform data operations. For example, in some embodiments the NPU region NPR may include a processor designed to perform machine learning or inference of a deep learning model. As the peripheral circuit layer 10 includes the NPU region NPR, the memory device 100A may be a processor-in-memory (PIM) type memory device capable of performing a data operation. For example, applications such as deep neural networks require computing systems with large-capacity computational and memory capabilities to more accurately train or learn different data sets, and PIM-type memory may perform some of the computation operations of the computing system through internal processing, thereby reducing the computation burden on the computing system.

In an embodiment, the NPU region NPR may be arranged on at least one side of the peripheral circuit region PR (e.g., in the second direction Y). For example, in an embodiment the peripheral circuit region PR may be arranged to extend in the first direction X from the central region of the peripheral circuit layer 10, and the NPU region NPR may be arranged on both sides of the peripheral circuit region PR (e.g., in the second direction Y).

In an embodiment, the NPU region NPR may include a per bank NPU or a bank dedicated NPU configured to perform a data operation such as an operation on a memory component included in a cell region CR arranged in the cell layer 30.

For example, in an embodiment as shown in FIG. 5, the peripheral circuit layer 10 may include a first NPU group NBG1 arranged on a first side of the peripheral circuit region PR (e.g., in the second direction Y) and a second NPU group NBG2 arranged on a second side opposite to the first side of the peripheral circuit region PR (e.g., in the second direction Y). In an embodiment, the first NPU group NBG1 may include a first NPU block NB1, a second NPU block NB2, and a third NPU block NB3 consecutively arranged in the first direction X, and the second NPU group NBG2 may include a fourth NPU block NB4, a fifth NPU block NB5, and a sixth NPU block NB6 consecutively arranged in the first direction X.

In an embodiment as shown in FIG. 6, the core layer 20 may include a core region COR, and the core region COR may include a first core bank group COBG1 that at least partially vertically overlaps the first NPU group NBG1, and a second core bank group COBG2 that at least partially vertically overlaps the second NPU group NBG2. For example, in an embodiment the first core bank group COBG1 may include first to third core banks COB1, COB2, and COB3 arranged side by side in the first horizontal direction X, and the second core bank group COBG2 may include fourth to sixth core banks COB4, COB5, and COB6 arranged side by side in the first horizontal direction X and spaced apart from the first to third core banks COB1, COB2, and COB3 in the second horizontal direction Y, respectively.

In an embodiment as shown in FIG. 7, the cell layer 30 may include a first cell bank group CBG1 arranged to at least partially vertically overlap the first NPU group NBG1, and a second cell bank group CBG2 arranged to at least partially vertically overlap the second NPU group NBG2. For example, in an embodiment the first cell bank group CBG1 may include first to third cell banks CB1, CB2, and CB3 arranged side by side in the first horizontal direction X, and the second cell bank group CBG2 may include fourth to sixth cell banks CB4, CB5, and CB6 arranged side by side in the first horizontal direction X and spaced apart from the first to third cell banks CB1, CB2, and CB3 in the second horizontal direction Y, respectively.

For example, the first NPU block NB1 may at least partially vertically overlap the first core bank COB1 and the first cell bank CB1, and may be electrically connected to the first core bank COB1 and the first cell bank CB1. In an embodiment, the first NPU block NB1 may be configured to perform an artificial intelligence algorithm operation on a memory component included in the first cell bank CB1. Likewise, the second to sixth NPU blocks NB2 to NB6 may be configured to perform an artificial intelligence algorithm operation on memory components included in the second to sixth cell banks CB2 to CB6, respectively.

In an embodiment, the peripheral circuit layer 10 may include a global bus region GBR, and the global bus region GBR may include a first global bus GB1 arranged between the peripheral circuit region PR and the first NPU group NBG1 (e.g., in the second horizontal direction Y), and a second global bus GB2 arranged between the peripheral circuit region PR and the second NPU group NBG2 (e.g., in the second horizontal direction Y). The first global bus GB1 may at least partially vertically overlap the first cell bank group CBG1, and may at least partially vertically overlap the first core bank group COBG1 and may be electrically connected therewith. The second global bus GB2 may at least partially vertically overlap the second cell bank group CBG2, and may at least partially vertically overlap the second core bank group COBG2 and may be electrically connected therewith.

In an embodiment, the first global bus GB1 may include circuits and/or data lines configured to enable data transfer among the first to third cell banks CB1, CB2, and CB3 of the first cell bank group CBG1. For example, in an embodiment the first global bus GB1 may include circuits and/or data lines configured to enable data transfer among the first to third cell banks CB1, CB2, and CB3 through the first to third core banks COB1, COB2, and COB3. For example, when data movement from the first cell bank CB1 to the second cell bank CB2 is required, data flow from the first cell bank CB1 to the first global bus GB1 through the first core bank COB1 may be implemented, and data flow from the first global bus GB1 to the second cell bank CB2 through the second core bank COB2 may be implemented.

In an embodiment, the first global bus GB1 may be configured to simultaneously enable data transfer among the first to third cell banks CB1, CB2, and CB3 of the first cell bank group CBG1. For example, in an embodiment the first global bus GB1 may be configured to simultaneously and in parallel implement data movement from the first cell bank CB1 to the second cell bank CB2 and data movement from the third cell bank CB3 to the first cell bank CB1.

Like the first global bus GB1, in an embodiment the second global bus GB2 may include a circuit configured to enable data transfer among the fourth to sixth cell banks CB4, CB5, and CB6 of the second cell bank group CBG2. In addition, in an embodiment the second global bus GB2 may be configured to simultaneously enable data transfer among the fourth to sixth cell banks CB4, CB5, and CB6 of the second cell bank group CBG2.

In an embodiment, in contrast to a comparative embodiment in which a cell region, a core region, and a peripheral circuit region are formed on one substrate, the chip size may be reduced, and the degree of freedom of space utilization of each of the peripheral circuit layer 10, the core layer 20, and the cell layer 30 may be increased. In addition, as NPU blocks and global buses are arranged on the peripheral circuit layer, simultaneous data input/output and high-speed data input/output between banks may be realized, and the electrical performance of the memory device 100A may be increased.

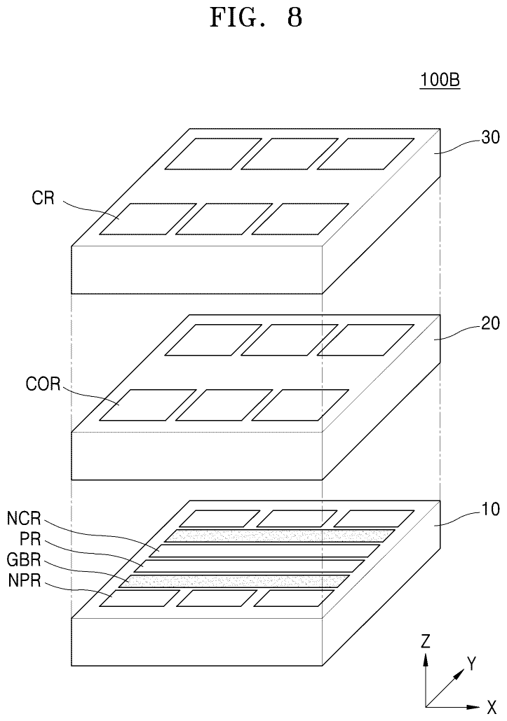

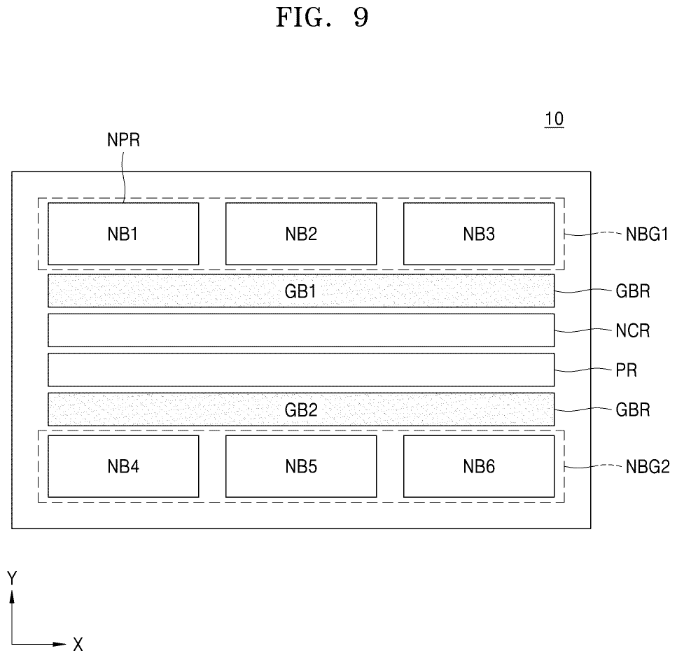

FIG. 8 is a perspective view illustrating a memory device 100B according to an embodiment. FIG. 9 is a plan view illustrating the peripheral circuit layer 10 of FIG. 8.

Referring to FIGS. 8 and 9, the memory device 100B may include a peripheral circuit layer 10, a core layer 20, and a cell layer 30 consecutively arranged in a vertical direction Z. The layout of the core layer 20 and the cell layer 30 may have characteristics similar to those of the core layer 20 and the cell layer 30 shown in embodiments of FIGS. 6 and 7.

In an embodiment as shown in FIG. 9, the peripheral circuit layer 10 may include a first NPU group NBG1 and a second NPU group NBG2, and may further include a common NPU region NCR. In an embodiment, the first NPU group NBG1 may include an NPU block electrically connected to the first core bank group COBG1 included in the core region COR and allocated to each core bank in the first core bank group COBG1, and the second NPU group NBG2 may include an NPU block electrically connected to the second core bank group COBG2 included in the core region COR and allocated to each core bank in the second core bank group COBG2. In an embodiment, the common NPU region NCR may include an NPU block existing “outside” each core bank. Here, the description that the common NPU region NCR includes NPUs existing outside each core bank means that the NPU included in the common NPU region NCR may control all of the core banks in the first core bank group COBG1 and all of the core banks in the second core bank group COBG2, thereby performing internal processing operations for all cell banks in the first cell bank group CBG1 and all cell banks in the second cell bank group CBG2.

In an embodiment, the common NPU region NCR may simultaneously perform various types of operation processing on the plurality of cell banks. For example, in an embodiment the common NPU region NCR may use a cell bank electrically connected to the first NPU group NBG1 through the first NPU group NBG1 and some cell banks electrically connected to the second NPU group NBG2 through the second NPU group NBG2 to perform simultaneous and parallel neural network operations.

For example, applications such as deep neural networks require computing systems with large-capacity computational and memory capabilities to more accurately train or learn different data sets. In an embodiment, the PIM-type memory may perform some of the computation operations of the computing system through internal processing, thereby reducing the computation burden on the computing system.

In an embodiment, the common NPU region NCR may be arranged between the global bus region GBR and the peripheral circuit region PR (e.g., in the second horizontal direction Y), and for example, the common NPU region NCR may be arranged between the first global bus GB1 and the peripheral circuit region PR (e.g., in the second horizontal direction Y). For example, as illustrated in FIG. 9, the peripheral circuit region PR and the first global bus GB1 may extend in the first horizontal direction X, and the common NPU region NCR may be arranged between the peripheral circuit region PR and the first global bus GB1 (e.g., in the second horizontal direction Y) to extend in the first horizontal direction X.

However, embodiments of the present inventive concept are not necessarily limited thereto. For example, in an embodiment, unlike the illustration in FIG. 9, the common NPU region NCR may be arranged between the second global bus GB2 and the peripheral circuit region PR (e.g., in the second horizontal direction Y). In this embodiment, the peripheral circuit region PR and the second global bus GB2 may extend in the first horizontal direction X and the common NPU region NCR may extend in the first horizontal direction X between the peripheral circuit region PR and the second global bus GB2 (e.g., in the second horizontal direction Y).

In an embodiment, the common NPU region NCR may be electrically connected to each NPU block in the first NPU group NBG1 through the first global bus GB1, may be electrically connected to all core banks in the first core bank group COBG1 through each NPU block in the first NPU group NBG1, and may also be electrically connected to all cell banks in the first cell bank group CBG1. Likewise, in an embodiment the common NPU region NCR may be electrically connected to each NPU block in the second NPU group NBG2 through the second global bus GB2, may be electrically connected to all core banks in the second core bank group COBG2 through each NPU block in the second NPU group NBG2, and may be electrically connected to all cell banks in the second cell bank group CBG2.

Since the memory device 100B according to an embodiment includes a common NPU region NCR as well as a plurality of NPU blocks electrically connected to a plurality of cell banks, simultaneous data input/output between banks and high-speed data input/output may be realized, and electrical performance of the memory device 100B may be increased.

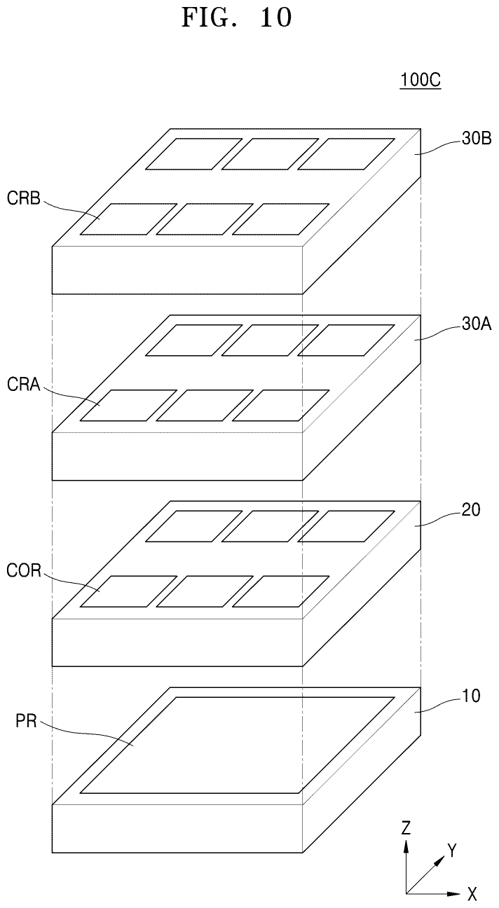

FIGS. 10 to 12 are perspective views illustrating a memory device 100C according to embodiments.

Referring to FIGS. 10 to 12, the memory device 100C may include a peripheral circuit layer 10, a core layer 20, a first cell layer 30A, and a second cell layer 30B consecutively arranged in a vertical direction Z. In an embodiment, the first cell layer 30A may include a first cell region CRA, and the second cell layer 30B may include a second cell region CRB. In an embodiment, the first cell layer 30A and the second cell layer 30B may be arranged to overlap each other in the vertical direction Z, and each of the first cell region CRA and the second cell region CRB may be a region in which memory components are arranged. For example, in an embodiment the memory components included in the first cell region CRA and the second cell region CRB may include at least one of a buried channel array transistor, a vertical channel transistor, a vertical stacked DRAM device, and a ferroelectric FET.

In some embodiments, the first cell region CRA and the second cell region CRB may include the same type of memory component as each other. However, embodiments of the present inventive concept are not necessarily limited thereto. For example, in an embodiment, the first cell region CRA and the second cell region CRB may include different types of memory components from each other. For example, in an embodiment the first cell region CRA may include a buried channel array transistor type memory component, and the second cell region CRB may include a ferroelectric FET type memory component.

In an embodiment, the first cell region CRA of the first cell layer 30A and the second cell region CRB of the second cell layer 30B may be electrically connected to the core circuit region COR in the core layer 20, and the first cell region CRA and the second cell region CRB may be electrically connected to the peripheral circuit region PR in the peripheral circuit layer 10 through the core circuit region COR.

In an embodiment, the peripheral circuit layer 10, the core layer 20, the first cell layer 30A, and the second cell layer 30B may be formed on separate wafers, respectively, and the peripheral circuit layer 10, the core layer 20, the first cell layer 30A, and the second cell layer 30B may be attached to each other by a wafer bonding method to form a memory device 100C having a four-stack structure. However, embodiments of the present inventive concept are not necessarily limited thereto. For example, in an embodiment, the memory device 100C having a four-stack structure may be formed by forming the peripheral circuit layer 10 on a base wafer and sequentially forming the core layer 20, the first cell layer 30A, and the second cell layer 30B on the base wafer. In an embodiment, the peripheral circuit layer 10 and the core layer 20 may be formed on separate wafers, respectively, the peripheral circuit layer 10 and the core layer 20 may be attached to each other in a wafer bonding manner, and then the first cell layer 30A and the second cell layer 30B are sequentially formed on the core layer 20 to form the memory device 100C having a four-stack structure.

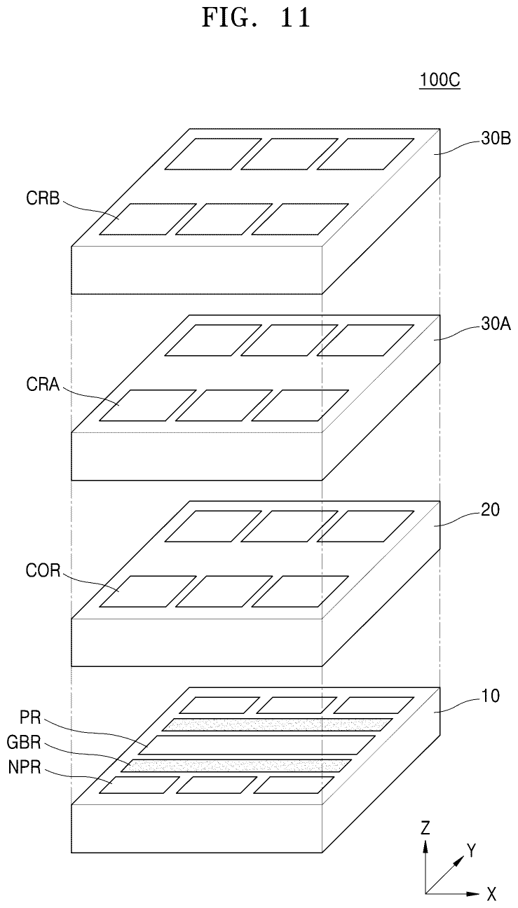

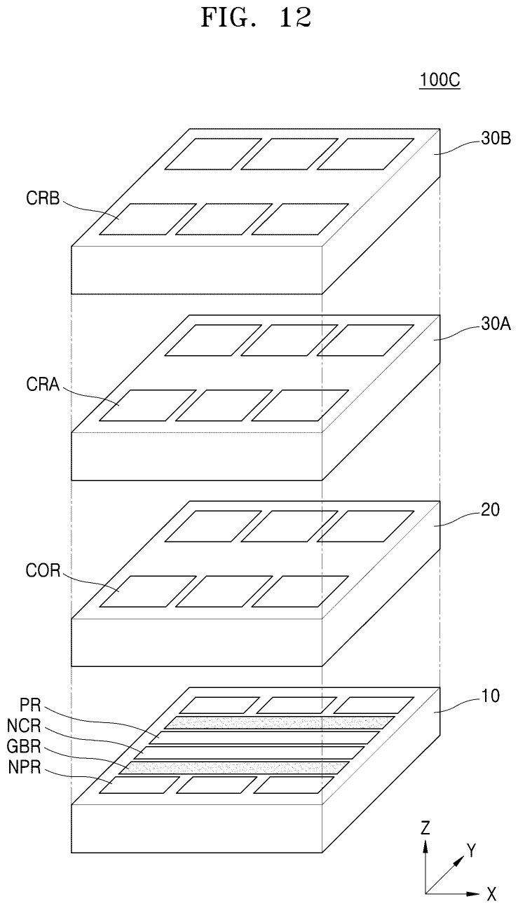

As shown in FIG. 10, in an embodiment the peripheral circuit layer 10 may include a peripheral circuit region PR arranged over a majority of, or the entire region of, the peripheral circuit layer 10. As shown in FIG. 11, in an embodiment the peripheral circuit layer 10 may include a peripheral circuit region PR, an NPU region NPR, and a global bus region GBR. For example, the technical features of the peripheral circuit region PR, the NPU region NPR, and the global bus region GBR may be similar to those described above with reference to embodiments shown in FIGS. 4 and 5. As shown in FIG. 12, in an embodiment the peripheral circuit layer 10 may include a peripheral circuit region PR, an NPU region NPR, a global bus region GBR, and a common NPU region NCR. Technical features of the common NPU region NCR may be similar to those described above with reference to embodiments of FIGS. 8 and 9.

In some embodiments, the memory device 100C may further include at least one third cell layer arranged at a vertical level higher than the second cell layer 30B. For example, the at least one third cell layer may include a third cell region in which memory components are arranged, and the third cell region may include a plurality of third cell banks. In some embodiments, a memory device 100C having a multi-stacked structure such as a 5-stack structure or a 6-stack structure may be formed as at least one third cell layer 30B (e.g., two or three or more vertically stacked third cell layers) is arranged above the second cell layer 30B.

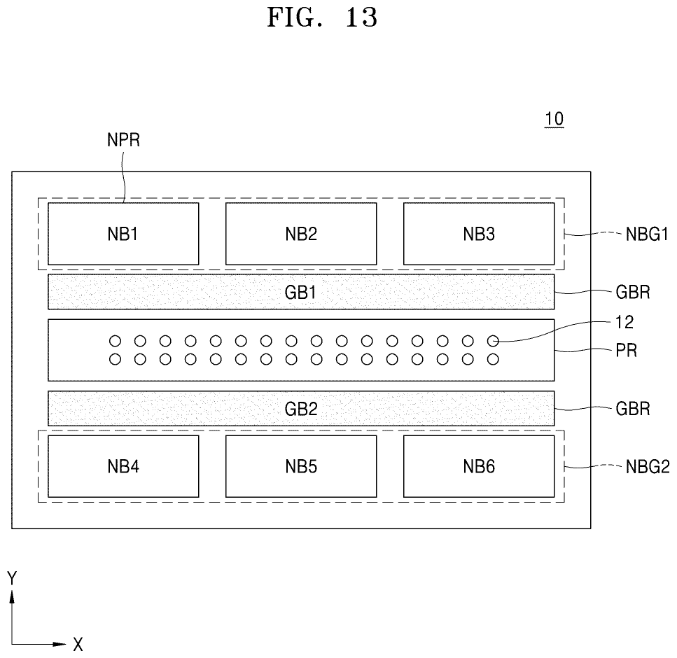

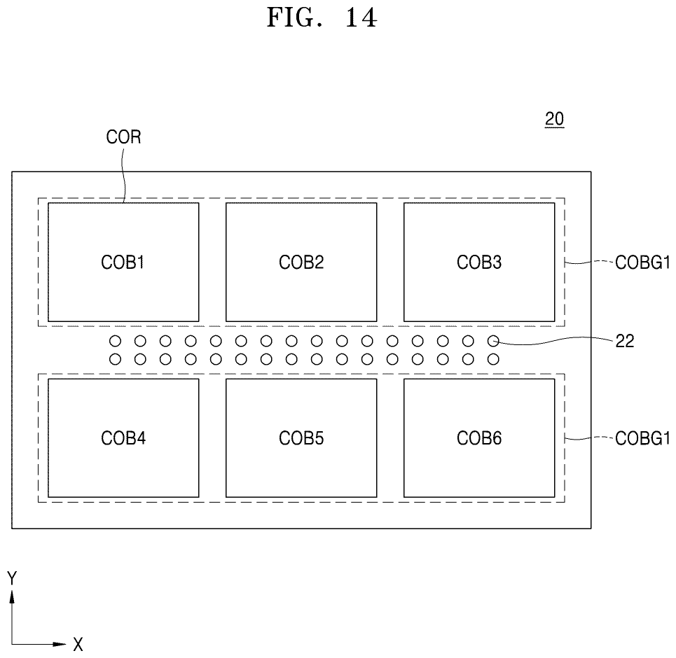

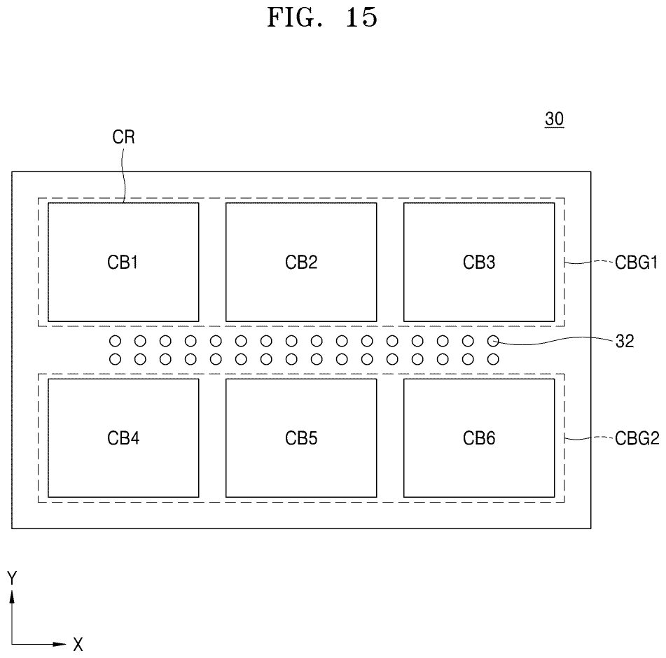

FIGS. 13 to 15 are plan views illustrating a memory device according to embodiments. Specifically, FIG. 13 is a plan view illustrating a peripheral circuit layer 10 of a memory device according to an embodiment. FIG. 14 is a plan view illustrating a core layer 20 of a memory device according to an embodiment. FIG. 15 is a plan view illustrating a cell layer 30 of a memory device according to an embodiment.

Referring to FIG. 13, the peripheral circuit layer 10 may include a through substrate via (TSV) 12 located in the center of the peripheral circuit layer 10. The TSV 12 may be located inside the peripheral circuit region PR. For example, the TSV 12 may be arranged between the first NPU group NBG1 and the second NPU group NBG2 in the second horizontal direction Y, and may be arranged between the first global bus GB1 and the second global bus GB2 in the second horizontal direction Y. The TSVs 12 may penetrate at least a portion of the peripheral circuit layer 10 (e.g., in the vertical direction Z).

Referring to FIG. 14, the core layer 20 may include TSVs 22 positioned at a central portion of the core layer 20. The TSVs 22 may be arranged between the first core bank group COBG1 and the second core bank group COBG2 in the second horizontal direction Y. The TSVs 22 may penetrate at least portions of the core layer 20 (e.g., in the vertical direction Z). The TSVs 22 may be electrically connected to the TSVs 12 included in the peripheral circuit layer 10. For example, the core circuit region COR of the core layer 20 may be electrically connected to the peripheral circuit region PR of the peripheral circuit layer 10 through the TSV 22 and the TSV 12.

Referring to FIG. 15, the cell layer 30 may include TSVs 32 positioned at a central portion of the cell layer 30. The TSVs 32 may be arranged between the first cell bank group CBG1 and the second cell bank group CBG2 in the second horizontal direction Y. The TSVs 32 may penetrate at least portions of the core layer 30 (e.g., in the vertical direction Z). The TSVs 32 may be electrically connected to the TSVs 22 included in the core layer 20. For example, the cell region CR of the cell layer 30 may be electrically connected to the core circuit region COR of the core layer 20 through the TSV 32 and the TSV 22.

In an embodiment, at least one of the TSV 12 included in the peripheral circuit layer 10, the TSV 22 included in the core layer 20, and the TSV 32 included in the cell layer 30 may be omitted. In an embodiment in which the TSV 12 included in the peripheral circuit layer 10 is omitted, the peripheral circuit layer 10 may further include a connection member connected to the TSV 22 included in the core layer 20. For example, in an embodiment the connection member may include a bonding pad, a bump pillar, or a solder bump.

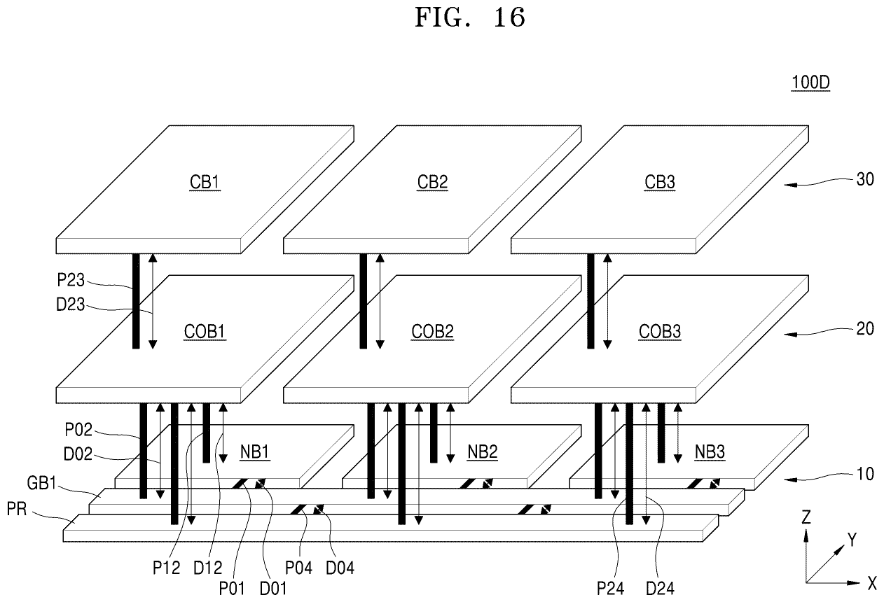

FIG. 16 is a schematic diagram illustrating data flow of a memory device 100D according to an embodiment.

Referring to FIG. 16, in an embodiment the peripheral circuit layer 10 may include a peripheral circuit region PR extending in the first horizontal direction X, a first global bus GB1 extending in the first horizontal direction X and spaced apart from the peripheral circuit region PR in the second horizontal direction Y, and first to third NPU blocks NB1, NB2, and NB3 sequentially arranged in the first horizontal direction X and spaced apart from the first global bus GB1 in the second horizontal direction Y. In an embodiment, the core layer 20 may include first to third core banks COB1, COB2, and COB3 sequentially arranged in the first horizontal direction X, and the cell layer 30 may include first to third cell banks CB1, CB2, and CB3 sequentially arranged in the first horizontal direction X.

In an embodiment, the first global bus GB1 may be connected to (e.g., electrically connected thereto) each of the first to third NPU blocks NB1, NB2, and NB3 through a connection wiring P01, and a data flow path D01 from each of the first to third NPU blocks NB1, NB2, and NB3 to the first global bus GB1 through the connection wiring P01 may be defined. In an embodiment, the first global bus GB1 may be connected to (e.g., electrically connected thereto) each of the first to third core banks COB1, COB2, and COB3 through a connection wiring P02, and a data flow path D02 from each of the first to third core banks COB1, COB2, and COB3 to the first global bus GB1 through the connection wiring P02 may be defined. In an embodiment, the first global bus GB1 may be connected to (e.g., electrically connected thereto) the peripheral circuit region PR through a connection line P04, and data flow path D04 from the peripheral circuit region PR to the first global bus GB1 through the connection line P04 may be defined.

In an embodiment, each of the first to third NPU blocks NB1, NB2, and NB3 may be connected to (e.g., electrically connected thereto) each of the first to third core banks COB1, COB2, and COB3 through a connection wiring P12, and a data flow path D12 from each of the first to third NPU blocks NB1, NB2, and NB3 to each of the first to third core banks COB1, COB2, and COB3 through the connection wiring P12 may be defined. In an embodiment, each of the first to third core banks COB1, COB2, and COB3 may be connected to (e.g., electrically connected thereto) each of the first to third cell banks CB1, CB2, and CB3 through a connection wiring P23, and a data flow path D23 from each of the first to third core banks COB1, COB2, and COB3 to each of the first to third cell banks CB1, CB2, and CB3 through the connection wiring P23 may be defined.

In some embodiments, data may be input/output or moved from the first to third core banks COB1, COB2, and COB3 to the peripheral circuit region PR through the first global bus GB1, as illustrated in FIG. 16. In an embodiment, each of the first to third core banks COB1, COB2, and COB3 may be connected to (e.g., electrically connected thereto) the peripheral circuit region PR through the connection wiring P24, and a data flow path D24 from each of the first to third core banks COB1, COB2, and COB3 to the peripheral circuit region PR through the connection wiring P24 may be defined. For example, data may be input/output or moved from the first to third core banks COB1, COB2, and COB3 to the peripheral circuit region PR by a direct data flow path without passing through the first global bus GB1.

In an embodiment, data may be moved from the first cell bank CB1 to the first core bank COB1 through the data flow path D23, from the first core bank COB1 to the first global bus GB1 through the data flow path D02, from the first global bus GB1 to the second core bank COB2 through the data flow path D02, and from the second core bank COB2 to the second cell bank CB2 through the data flow path D23. Therefore, data may be moved from the first cell bank CB1 to the second cell bank CB2 through the shortest data movement path.

In a memory device according to a comparative embodiment in which a global bus is not included, a redundant data movement occurs because data flows or moves from one bank to another bank through an external CPU device. In addition, in a memory device according to a comparative embodiment in which a global bus is not included, it is difficult to input external input data to multiple banks at the same time.

However, according to an embodiment of the present inventive concept, redundancy of data movement may be reduced by using the first global bus GB1 when data is moved between banks. In addition, input data may be input to multiple banks at the same time using the first global bus GB1, and high-speed parallel operations required for neural network operations related to machine learning or deep learning may be realized.

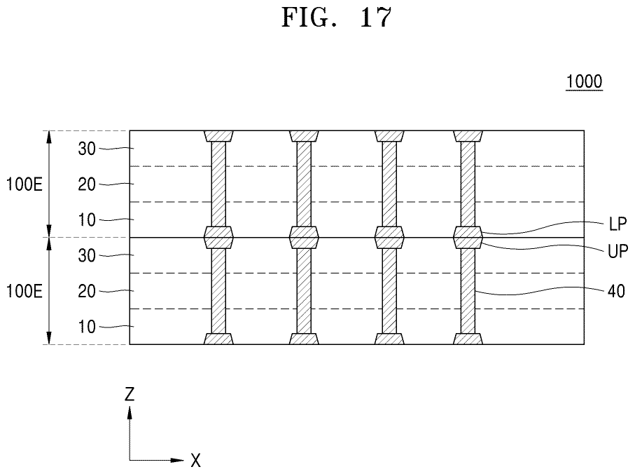

FIG. 17 is a cross-sectional view illustrating a semiconductor package 1000 according to an embodiment.

Referring to FIG. 17, a semiconductor package 1000 may include a plurality of memory dies 100E stacked in a vertical direction Z. For example, each of the plurality of memory dies 100E may include at least one of the memory devices described with reference to FIGS. 1 to 16. While an embodiment of FIG. 17 shows the plurality of memory dies 100E having two memory dies, embodiments of the present inventive concept are not necessarily limited thereto and the number of the plurality of memory dies 100E may vary.

For example, in an embodiment each of the plurality of memory dies 100E may have a structure in which a peripheral circuit layer 10, a core layer 20, and a cell layer 30 are vertically stacked. A TSV 40 penetrating each of the plurality of memory dies 100E (e.g., in the vertical direction Z) may be arranged. Each of the plurality of memory dies 100E may include a lower pad LP and an upper pad UP on the lower and upper surfaces thereof. In an embodiment, the plurality of memory dies 100E may be electrically connected by bonding the upper pad UP of the memory die 100E arranged below and the lower pad LP of the memory die 100E arranged above to each other. The lower pad LP and the upper pad UP may be electrically connected to the TSV 40. For example, in an embodiment the lower pad LP and the upper pad UP may be conductive pads or conductive bumps.

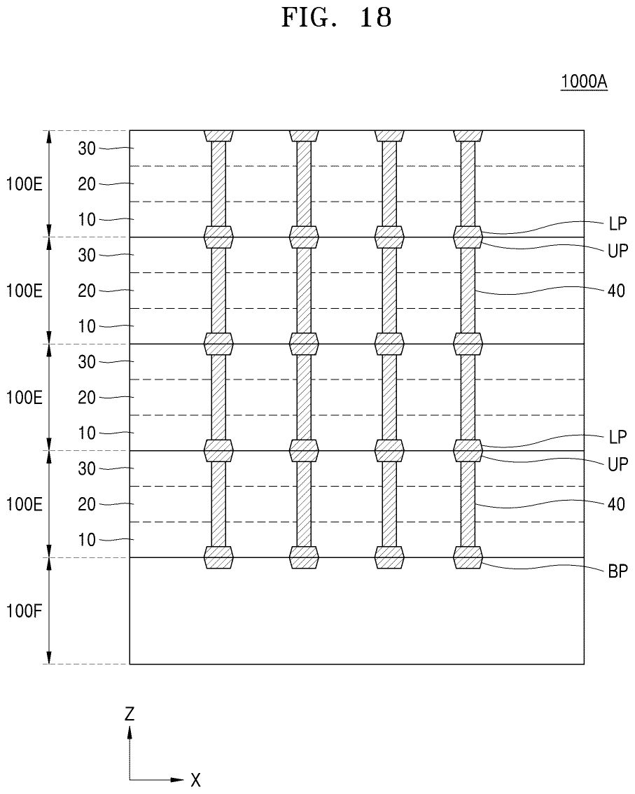

FIG. 18 is a cross-sectional view illustrating a semiconductor package 1000A according to an embodiment.

Referring to FIG. 18, a semiconductor package 1000A may include a base die 100F and a plurality of memory dies 100E stacked on the base die 100F in a vertical direction Z. For example, each of the plurality of memory dies 100E may include at least one of the memory devices described with reference to FIGS. 1 to 16. While an embodiment of FIG. 18 shows the plurality of memory dies 100E having four memory dies, embodiments of the present inventive concept are not necessarily limited thereto and the number of the plurality of memory dies 100E may vary.

The base die 100F may be electrically connected to the plurality of memory dies 100E, and may include a host core or a buffer die. In an embodiment, the host core may include a processor that performs various computational operations. The buffer die may receive commands, data, signals, and the like transmitted from the outside, and transmit the received results to the plurality of memory dies 100E.

In an embodiment, the plurality of memory dies 100E may be electrically connected to the base die 100F by TSVs 40 penetrating each of the plurality of memory dies 100E (e.g., in the vertical direction Z). A connection pad BP may be arranged on a top surface of the base die 100F. The TSVs 40 of the lowermost memory die 100E among the plurality of memory dies 100E may be electrically connected to the base die 100F through the lower pad LP and the connection pad BP connected thereto.

In an embodiment, unlike the illustration in FIG. 18, at least one of the plurality of memory dies 100E (e.g., the uppermost memory die 100E) may not include the TSVs 40.

According to embodiments of the present inventive concept described above, a memory device may have a three-stack structure in which a peripheral circuit layer, a core layer, and a cell layer are vertically stacked, and thus a chip size may be reduced and a degree of freedom in space utilization of each layer may be increased. In addition, as NPU blocks and global buses are arranged in the peripheral circuit layer, efficient data input/output between banks may be possible, and the performance of memory devices may be increased.

While the present inventive concept has been particularly shown and described with reference to embodiments thereof, it will be understood that various changes in form and details may be made to the described embodiments without departing from the spirit and scope of the present inventive concept.

What is claimed is:

1. A memory device comprising:
a peripheral circuit layer including a peripheral circuit region;
a cell layer arranged at a different vertical level from the peripheral circuit layer, the cell layer including a cell region; and
a core layer arranged between the peripheral circuit layer and the cell layer in a vertical direction, the core layer including a core circuit region electrically connected to the peripheral circuit region and the cell region, wherein
the cell region includes a plurality of cell banks, each of the plurality of cell banks including a memory component,
the core circuit region includes a plurality of core banks arranged at positions at least partially vertically overlapping the plurality of cell banks, respectively, and each of the plurality of core banks includes a core circuit.

2. The memory device of claim 1, wherein:
the peripheral circuit layer further includes a neural processing unit (NPU) region; and
the NPU region comprises a plurality of NPU blocks at least partially vertically overlapping each of the plurality of core banks, respectively.

3. The memory device of claim 2, wherein:
a first cell bank among the plurality of cell banks vertically overlaps at least a portion of a first core bank among the plurality of core banks; and
the first cell bank among the plurality of cell banks vertically overlaps at least a portion of a first NPU block among the plurality of NPU blocks.

4. The memory device of claim 2, wherein:
the peripheral circuit layer further includes a global bus region;
the global bus region is electrically connected to at least two core banks among the plurality of core banks and at least two cell banks among the plurality of cell banks; and
the global bus region provides data flow between the at least two cell banks and the at least two core banks.

5. The memory device of claim 4, wherein the peripheral circuit region extends in a first horizontal direction, and
the global bus region comprises:
a first global bus arranged on a first side of the peripheral circuit region in a second horizontal direction crossing the first horizontal direction; and
a second global bus arranged on a second side of the peripheral circuit region in the second horizontal direction.

6. The memory device of claim 5, wherein the core circuit region includes a first core bank group and a second core bank group adjacent to each other in the second horizontal direction, wherein
the first core bank group is electrically connected to the first global bus, and
the second core bank group is electrically connected to the second global bus.

7. The memory device of claim 4, wherein the NPU region further comprises a common NPU region arranged between the global bus region and the peripheral circuit region.

8. The memory device of claim 1, wherein the memory component includes at least one of a buried channel array transistor, a vertical channel transistor, a vertical stacked DRAM device, and a ferroelectric field-effect transistor (FET).

9. The memory device of claim 1, wherein:
the core circuit includes at least one of a planar field-effect transistor (FET) device, a FET device having a metal gate and a high-dielectric-constant dielectric film, a finFET device, and a multi-bridge channel FET device; and
the peripheral circuit region includes a peripheral circuit, and the peripheral circuit includes at least one of a planar FET device, a finFET device, and a multi-bridge channel FET device.

10. The memory device of claim 1, wherein:
each of the cell layer and the core layer further includes through-substrate vias (TSVs); and
the TSVs of the cell layer and the TSVs of the core layer are electrically connected to each other.

11. The memory device of claim 1, wherein the cell layer further comprises:
a first cell layer including a plurality of first cell banks, each of the plurality of first cell banks including a memory component;
a second cell layer including a plurality of second cell banks, each of the plurality of second cell banks including a memory component, the second cell layer is arranged at a higher vertical level than the first cell layer; and
a third cell layer including a plurality of third cell banks, each of the plurality of third cell banks including a memory component, the third cell layer is arranged at a higher vertical level than the second cell layer.

12. A memory device comprising:
a peripheral circuit layer including a peripheral circuit region and a neural processing unit (NPU) region;
a core layer arranged on the peripheral circuit layer, the core layer including a core circuit region electrically connected to the peripheral circuit region and the NPU region; and
a first cell layer arranged at a vertical level higher than the core layer, the first cell layer including a first cell region electrically connected to the core circuit region,
wherein the first cell region includes a plurality of first cell banks, each of the plurality of first cell banks including a memory component, and
the NPU region includes a plurality of NPU blocks performing an operation function on the plurality of first cell banks.

13. The memory device of claim 12, wherein:
the core circuit region includes a plurality of core banks arranged at positions at least partially vertically overlapping the plurality of first cell banks, respectively; and
the plurality of core banks at least partially vertically overlaps the plurality of NPU blocks, respectively.

14. The memory device of claim 13, wherein the peripheral circuit layer further includes a global bus region,
the global bus region is electrically connected to at least two core banks among the plurality of core banks and at least two first cell banks among the plurality of first cell banks; and
the global bus region provides data flow between the at least two first cell banks and the at least two core banks.

15. The memory device of claim 14, wherein the NPU region further comprises a common NPU region arranged between the global bus region and the peripheral circuit region.

16. The memory device of claim 14, further comprising:
a second cell layer arranged at a higher vertical level than the first cell layer, the second cell layer including a second cell region electrically connected to the core circuit region,
wherein the second cell region includes a plurality of second cell banks, each of the plurality of second cell banks including a memory component.

17. The memory device of claim 16, further comprising at least one third cell layer arranged at a higher vertical level than the second cell layer, the at least one third cell layer is electrically connected to the core circuit region, wherein the at least one third cell layer includes a plurality of third cell banks, each of the plurality of third cell banks including a memory component.

18. A semiconductor package comprising:
a plurality of memory dies vertically stacked; and
through-substrate vias (TSVs) electrically connecting the plurality of memory dies with each other,
wherein each of the plurality of memory dies comprises:
a peripheral circuit layer including a peripheral circuit region;
a core layer arranged at a higher vertical level than the peripheral circuit layer, the core layer including a core circuit region electrically connected to the peripheral circuit region; and
a cell layer arranged at a vertical level higher than the core layer, the cell layer including a cell region electrically connected to the core circuit region,
wherein the cell region includes a plurality of cell banks, each of the plurality of cell banks including a memory component,
the core circuit region includes a plurality of core banks arranged at positions at least partially vertically overlapping the plurality of cell banks, respectively, and each of the plurality of core banks includes a core circuit.

19. The semiconductor package of claim 18, further comprising a base die comprising a host core or a buffer die, the plurality of memory dies are arranged on the base die,
wherein the peripheral circuit layer further comprises:
a neural processing unit (NPU) region including a plurality of NPU blocks at least partially vertically overlapping the plurality of core banks, respectively; and
a global bus region electrically connected to at least two core banks among the plurality of core banks.

20. The semiconductor package of claim 19, wherein the peripheral circuit region extends in a first horizontal direction, and
the global bus region comprises:
a first global bus arranged on a first side of the peripheral circuit region in a second horizontal direction crossing the first horizontal direction; and
a second global bus arranged on a second side of the peripheral circuit region in the second horizontal direction, and
the core circuit region comprises a first core bank group and a second core bank group adjacent to each other in the second horizontal direction,
wherein the first core bank group is electrically connected to the first global bus, and
the second core bank group is electrically connected to the second global bus.
